(19) United States
(12) Patent Application Publication
(10) Pub. No.: US 2009/0015295 A1
(43) Pub. Date: Jan. 15, 2009

(54) Envelope detector having reduced harmonic interference

(75) Inventors: Ichiro Aoki, San Clemente, CA (US); Setu Mohta, Tustin, CA (US); David Kang, Fullerton, CA (US)

Correspondence Address: Mr. Christopher John Rourk;Jackson Walker LLP, 901 Main Street, Suite 6000, DALLAS, TX, 75202, US

(73) Assignee: Axiom Microdevices, Inc.

(21) Appl. No.: 11/827,184

(22) Filed: Jul. 11, 2007

(51) Int. Cl. H03K 5/153

(52) U.S. Cl. 327/58

(57) ABSTRACT

A system for detecting the envelope of a signal is provided. The system includes a first envelope detector generating a first envelope signal of an input RF signal, such as an envelope signal representing the positive peak envelope of the input RF signal. A second envelope detector generates a second envelope signal of the input RF signal, such as an envelope signal representing the negative peak envelope of the input RF signal. A signal combiner receives the first envelope signal and the second envelope signal and generates an even-order harmonic compensated envelope signal, such as by compensating for the difference between the positive peak envelope and the negative peak envelope.

### FIELD OF THE INVENTION

The present invention pertains to the field of envelope detectors, and more particularly to a system and method for detecting the envelope of an RF signal that compensates for even-order harmonics without requiring pre-processing of the RF signal with harmonic filters to reject even-order harmonics.

### BACKGROUND OF THE INVENTION

Envelope detectors are known in the art. Envelope detectors can be used to generate an output signal representing the envelope level or amplitude of a high frequency input signal. This can be used in many applications, such as demodulating an amplitude modulated input signal, detecting the strength of a received RF signal, detecting the level of a generated RF signal for use in amplitude leveling loops, detecting the level of a generated RF signal for use in a amplitude feedback loop such as in a polar modulator, or other applications.

FIG. 1 is a schematic diagram of a prior art envelope detector. Envelope detector 100 comprises rectifying transistor 101, capacitor 102, holding capacitor 103, and bias current 104. Rectifying transistor 101 receives an input RF signal at a first terminal through capacitor 102. The first terminal of rectifying transistor 101 can be the gate if rectifying transistor 101 is a field-effect transistor (FET), the base if rectifying transistor 101 is a bipolar transistor, or other suitable transistor control terminal inputs.

A second terminal of rectifying transistor 101 is connected to holding capacitor 103 at an output node 105 and is provided a bias current 104. The second terminal of rectifying transistor 101 can be the source if rectifying transistor 101 is a FET, the emitter if rectifying transistor 101 is a bipolar transistor, or other suitable transistor conducting terminals. Holding capacitor 103 is selected so that the response time of the voltage at output node 105 is substantially slower than the frequency of the RF input. By using a nonlinear rectifying transistor 101, the average voltage at output node 105 will track the peak value of the RF input if rectifying transistor 101 produces a large current into holding capacitor 103 when the voltage on its first terminal is larger than the voltage on output node 105 plus a threshold voltage or turn-on voltage but is small otherwise. This response characteristic allows rectifying transistor 101 to quickly increase the voltage on output node 105 as the peak voltage of the RF input increases, while holding capacitor 103 and bias current 104 form a slow discharge circuit to allow the voltage to reduce when the peak voltage of the RF input reduces.

Similar configurations exist to track the negative peak voltage, such as using a p-type FET or a PNP bipolar transistor for rectifying transistor 101. Other configurations of envelope detectors are also known in the art, such as using PN junction diodes or circuits using several transistors to track positive or negative peak voltage.

FIG. 2 depicts operating waveforms 200 of a prior art envelope detector, such as envelope detector 100. Waveform 201 depicts an exemplary RF input signal having a high frequency RF signal with slowly changing amplitude. Waveform 202 depicts the peak voltage detected at the output of the envelope detector, such as output node 105, if the envelope detector is detecting the positive signal peaks. By tracking the peak voltage, the low frequency amplitude modulation can be recovered while substantially removing the high frequency of the RF signal.

In many cases, the RF input signal contains modulated harmonic frequencies as well as the modulated carrier frequency. However, the envelope detector output should contain the envelope of the modulated carrier frequency only, such that the harmonic frequencies represent an interference signal that can result in misoperation of the envelope detector. For instance, in a polar modulation system using an envelope detector to implement an amplitude feedback loop, it is necessary to carefully control the modulation of the carrier frequency, and the effect of harmonics in the RF signal is to interfere with such control. In other applications, such as AM demodulation and signal strength indication, the presence of harmonic frequencies in the detected envelope can also have a detrimental effect.

FIG. 3 depicts operating waveforms 300 of a prior art envelope detector, such as envelope detector 100, when carrier and harmonic frequencies are both present at the input. In this case, a second harmonic is present at the input, where the amplitude of the second harmonic relative to the carrier increases as the carrier level increases. This additional carrier-level dependent second harmonic can be present if a nonlinear device such as a power amplifier has acted on the signal. The added second harmonic can change the level of the signal peaks in a manner which is dependent on the relative phase of the carrier and the harmonic. If the carrier and harmonic are aligned at their peaks, then the peak of the composite signal can be the sum of the peaks of the carrier and the harmonic signals taken separately. This case is depicted as waveform 301, representing an input RF signal with second harmonic interference, where the dashed line of waveform 202 represents the peak value of the carrier signal. The detected peak voltage using a prior envelope detector is depicted as waveform 203. Due to the presence of the harmonic signal, waveform 203 does not accurately represent the envelope of the carrier, which is waveform 202.

Filters can be used to reject the harmonic frequency at a prior stage so that they are not coupled to the envelope detector, but filters require additional circuitry, increase fabrication cost, and can also generate noise that can affect other system components.

### SUMMARY OF THE INVENTION

In accordance with the present invention, an envelope detector is provided that detects the amplitude of an input RF signal with reduced sensitivity to harmonic interference, and which does not require harmonic filters to achieve this reduction.

In particular, an envelope detector and method of operation are provided that utilize the positive and negative envelopes to reduce the effect of even order harmonics on the envelope signal.

In accordance with an exemplary embodiment of the invention, a system for detecting the envelope of a signal is provided. The system includes a first envelope detector generating a first envelope signal of an input RF signal, such as an envelope signal representing the positive peak envelope of the input RF signal. A second envelope detector generates a second envelope signal of the input RF signal, such as an envelope signal representing the negative peak envelope of the input RF signal. A signal combiner receives the first envelope signal and the second envelope signal and generates an even-order harmonic compensated envelope signal, such as by compensating for the difference between the positive peak envelope and the negative peak envelope.

The present invention provides many important technical advantages. One important technical advantage of the present invention is a system and method for detecting the envelope of an RF signal that compensates for even-order harmonics without the need for pre-processing the input RF signal with even-order harmonic filters.

Those skilled in the art will further appreciate the advantages and superior features of the invention together with other important aspects thereof on reading the detailed description that follows in conjunction with the drawings.

### BRIEF DESCRIPTION OF THE DRAWINGS

FIG. 1 is a schematic diagram of a prior art envelope detector;

FIG. 2 depicts operating waveforms of a prior art envelope detector;

FIG. 3 depicts operating waveforms of a prior art envelope detector when carrier and harmonic frequencies are both present at the input;

FIG. 4 is a schematic diagram of an envelope detector in accordance with an exemplary embodiment of the present invention;

FIG. 5 is a diagram of operating waveforms of an envelope detector in accordance with an exemplary embodiment of the present invention;

FIG. 6 is a schematic diagram of an envelope detector in accordance with an exemplary embodiment of the present invention; and

FIG. 7 is a schematic diagram of an envelope detector in accordance with an exemplary embodiment of the present invention.

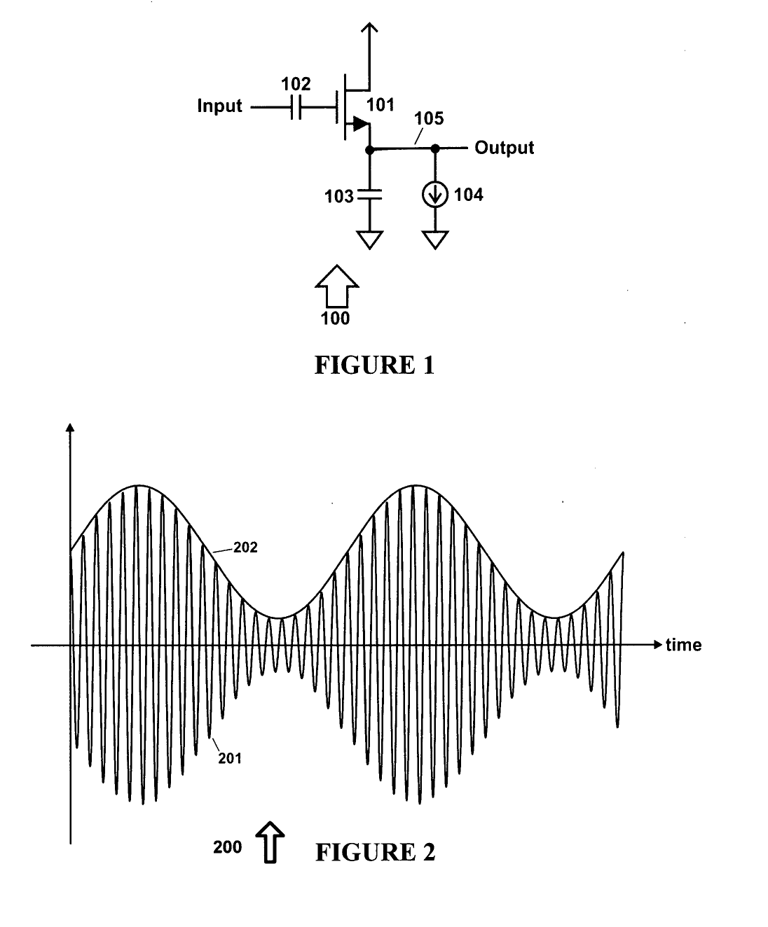

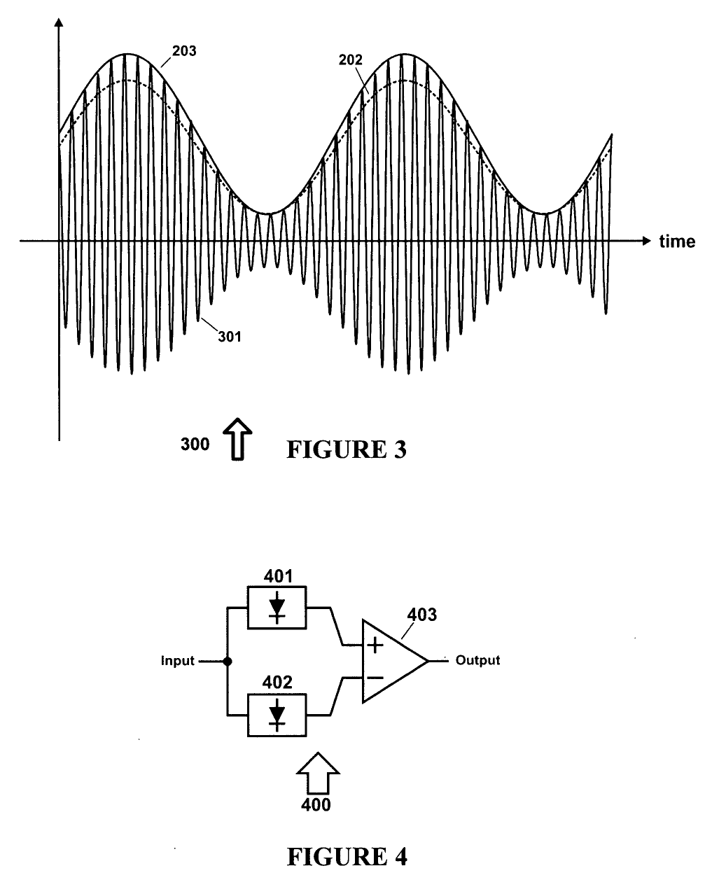

### DETAILED DESCRIPTION OF PREFERRED EMBODIMENTS

In the description which follows, like parts are marked throughout the specification and drawing with the same reference numerals, respectively. The drawing figures may not be to scale and certain components may be shown in generalized or schematic form and identified by commercial designations in the interest of clarity and conciseness.

FIG. 4 is a diagram of an envelope detector 400 in accordance with an exemplary embodiment of the present invention. Envelope detector 400 includes positive peak envelope detector 401, negative peak envelope detector 402 and signal combiner 403. Positive peak envelope detector 401 receives an RF input signal as an input and produces an output related to the positive peak values of the input RF signal. Negative peak envelope detector 402 receives the RF input signal as an input and produces an output related to the negative peak values of the input RF signal. Signal combiner 403 receives the outputs of positive peak envelope detector 401 and negative peak envelope detector 402, and produces an output signal representing the detected envelope of the input RF signal. In one exemplary embodiment, positive peak envelope detector 401 outputs a voltage that represents the positive peak level of the input RF signal and negative peak envelope detector 402 outputs a voltage that represents the negative peak level of the RF input signal. In this exemplary embodiment, signal combiner 403 can be a difference amplifier, outputting an amplified representation of the difference between the output of positive peak envelope detector 401 and negative peak envelope detector 402, or other suitable systems or processes can also or alternatively be used.

In operation, envelope detector 400 provides reduced sensitivity to even-order input harmonics, such as the second harmonic, of the RF input signal carrier frequency, by combining the outputs of positive peak envelope detector 401 and negative peak envelope detector 402, so that the detected carrier frequency signal envelope components add together but that the detected harmonic signal envelope components offset each other, so as to cancel or substantially cancel the components of the envelope created by harmonic frequencies. In this manner, envelope detector 400 achieves harmonic filtering without the need for pre-processing of the RF signal with harmonic filters.

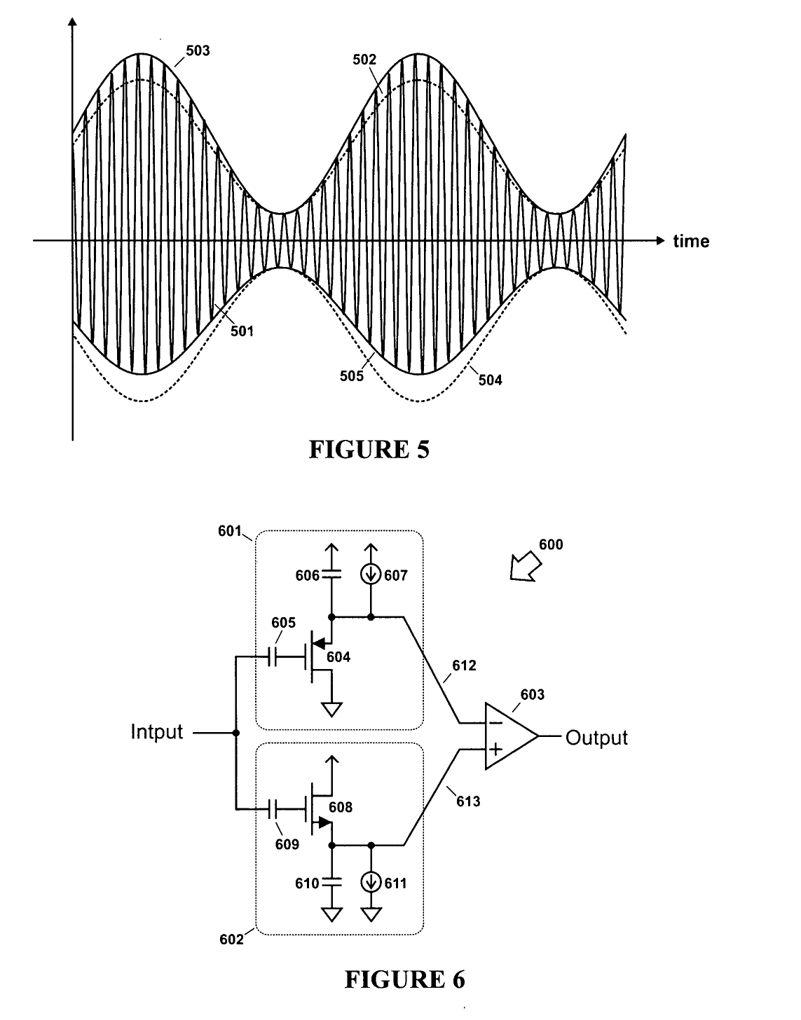

FIG. 5 is a diagram 500 of operating waveforms of an envelope detector in accordance with an exemplary embodiment of the present invention, such as envelope detector 400. Waveform 501 represents an RF input signal with amplitude modulated carrier and harmonic frequencies. Dashed line 502 represents the positive peak level of the carrier frequency signal, and dashed line 504 represents the negative peak level of the carrier frequency signal. Due to the presence of the harmonic signal, the positive and negative peak levels of the composite input RF signal are depicted by waveforms 503 and 505 respectively. These signals can be detected using positive peak envelope detector 401 and negative peak envelope detector 402, or other suitable detectors. As can be seen, the positive peak level 503 is increased above the carrier signal positive peak level 502 by approximately the same amount that the negative peak level 505 is increased above the carrier signal negative peak level. By subtracting negative peak level 505 from positive peak level 503, such as by using signal combiner 403, the envelope of this error signal can be canceled while preserving the envelope of the carrier signal, resulting in a signal that is substantially the same as if carrier positive peak level 502 and carrier negative peak level 504 had been used. This reduction can occur in any even harmonic frequency, as even harmonic frequencies typically increase or decrease the positive and negative peak levels of a signal by the same amount.

FIG. 6 is a diagram of an envelope detector 600 in accordance with an exemplary embodiment of the present invention. Envelope detector 600 includes negative peak envelope detector 601, positive peak envelope detector 602 and differencing amplifier 603.

Negative peak envelope detector 601 includes rectifying transistor 604, capacitor 605, and holding capacitor 606. Rectifying transistor 604 can be a PNP transistor, a p-type FET, or other suitable devices for detecting negative peak voltages. An RF input signal is coupled through capacitor 605 to a gate, base, or other suitable control terminal of rectifying transistor 604. A source, emitter or other suitable control terminal of rectifying transistor 604 is connected to holding capacitor 606 and is provided with bias current 607. The nonlinearity of rectifying transistor 604 is used to produce an output signal 612 related to the level of the negative peaks of the RF input signal.

Positive peak envelope detector 602 includes rectifying transistor 608, capacitor 609, and holding capacitor 610. Rectifying transistor 608 can be an NPN transistor, an n-type FET, or other suitable devices for detecting negative peak voltages. The RF input signal is coupled through capacitor 609 to a gate, base or other suitable control terminal of rectifying transistor 608. A source, emitter or other suitable conducting terminal of rectifying transistor 608 is connected to holding capacitor 610 and is provided with a bias current 611. The nonlinearity of rectifying transistor 608 is used to produce an output signal 613 that is related to the level of the positive peaks of the RF input signal.

Differencing amplifier 603 subtracts the output signals 612 and 613 of negative peak envelope detector 601 and positive peak envelope detector 602, respectively, to produce an output signal that corresponds to the envelope of the detected carrier level. By subtracting the positive and negative peak levels, differencing amplifier 603 cancels even-order harmonic interference generated on detected output signals 612 and 613. Since detected output signal 612 decreases with increasing carrier amplitude while detected output signal 613 increases with increasing carrier amplitude, the detected signal due to the envelope of the carrier signal is retained after the subtraction.

Differencing amplifier 603 can be implemented using a differential pair, by transforming output signals 612 and 613 into currents and subtracting the resulting currents, or in other suitable manners to perform the subtraction of the even harmonic envelope components. In one exemplary embodiment, differencing amplifier 603 can be implemented using an operational amplifier, such as by using an appropriate feedback network to accomplish the subtraction.

In operation, envelope detector 600 detects the envelope of an input RF signal without degradation from even harmonics, such as second harmonics, that may be present in the signal. In this manner, envelope detector 600 may not require second harmonic filters to be used, which can create noise or other undesired effects on other system components and which increase the cost and size of the overall circuit.

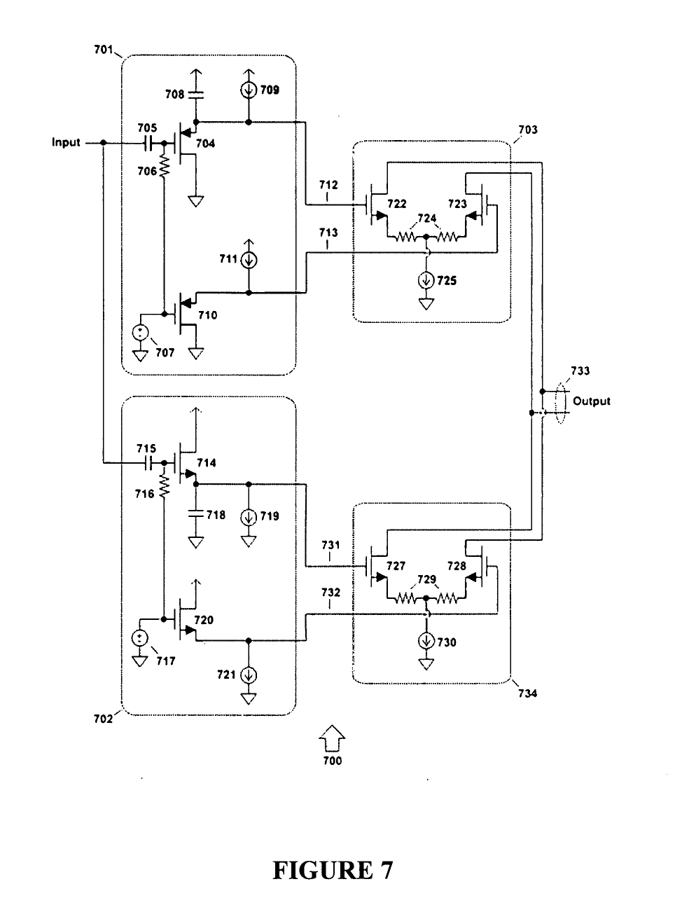

FIG. 7 is a diagram of an envelope detector 700 in accordance with an exemplary embodiment of the present invention. Envelope detector 700 includes negative peak envelope detector 701, positive peak envelope detector 702, differential amplifier 703 and differential amplifier 734.

Negative peak envelope detector 701 includes rectifying transistor 704, capacitor 705, resistor 706, holding capacitor 708 and replica rectifying transistor 710. A gate, base or other suitable control terminal of rectifying transistor 704 receives an input RF signal through capacitor 705, and receives a bias voltage 707 through resistor 706. A source, emitter or other suitable conducting terminal of rectifying transistor 704 is connected to holding capacitor 708 and is provided with bias current 709 to generate output signal 712. The nonlinearity of rectifying transistor 704 produces output signal 712 representing the level of the negative peaks of the input RF signal. Rectifying transistor 704 can be a PNP transistor, a p-type FET, or other suitable devices for detecting negative peak voltages.

Replica rectifying transistor 710 is matched to rectifying transistor 704, such as by using the same physical dimensions for both devices and keeping them in close proximity to one another when implemented in an integrated circuit, so as to reduce the effect of material or process variations. Replica rectifying transistor 710 receives bias voltage 707 at a gate, base or other suitable control terminal and is provided with bias current 711 at a source, emitter or other suitable conducting terminal to generate offset signal 713. By utilizing rectifying transistors 710 and 704 with matching characteristics and bias currents 709 and 711 with matching characteristics, the offset signal 713 has the same signal value as output signal 712 has when the RF input has zero amplitude. Thus, offset signal 713 can be subtracted from output signal 712 to produce a detected output with little or no zero DC offset.

Positive peak envelope detector 702 includes rectifying transistor 714, capacitor 715, resistor 716, holding capacitor 718 and replica rectifying transistor 720. A gate, base or other suitable control terminal of rectifying transistor 714 receives an input RF signal through capacitor 715, and receives a bias voltage 717 through resistor 716. A source, emitter or other suitable conducting terminal of rectifying transistor 714 is connected to holding capacitor 718 and is provided with bias current 719 to generate output signal 731. The nonlinearity of rectifying transistor 714 produces output signal 731 representing the level of the positive peaks of the input RF signal. Rectifying transistor 714 can be a NPN transistor, an n-type FET, or other suitable devices for detecting positive peak voltages.

Replica rectifying transistor 720 is matched to rectifying transistor 714, such as by using the same physical dimensions for both devices and keeping them in close proximity to one another when implemented in an integrated circuit, so as to reduce the effect of material or process variations. Replica rectifying transistor 720 receives bias voltage 717 at a gate, base or other suitable control terminal and is provided with bias current 721 at a source, emitter or other suitable conducting terminal to generate output offset signal 732. By utilizing rectifying transistors 720 and 714 with matching characteristics and bias currents 719 and 721 with matching characteristics, the offset signal 732 has the same signal value as output signal 731 has when the RF input has zero amplitude. Thus, offset signal 732 can be subtracted from output signal 731 to produce a detected output with little or no zero DC offset.

Differential amplifier 703 includes transistor 722, transistor 723 and optional resistors 724. Transistors 722 and 723 can be configured as a differential pair or in other suitable manners. Transistor 722 receives output signal 712 at a gate, base or other control terminal, and transistor 723 receives offset signal 713 at a gate, base, or other suitable control terminal. Optional resistors 724 can be used to control the gain of output signal 712 and offset signal 713 through transistors 722 and 723. Transistors 722 and 723 produce a differential output current or other suitable currents at their drains or collectors, which represent a scaled version of the difference between output signal 712 and offset signal 713.

Differential amplifier 734 includes transistor 727, transistor 728 and optional resistors 729. Transistors 727 and 728 can be configured as a differential pair or in other suitable manners. Transistor 727 receives output signal 731 at a gate, base or other control terminal, and transistor 728 receives offset signal 732 at a gate, base, or other suitable control terminal. Optional resistors 729 can be used to control the gain of output signal 731 and offset signal 732 through transistors 727 and 728. Transistors 727 and 728 produce a differential output current or other suitable currents at their drains or collectors, which represent a scaled version of the difference between output signal 731 and offset signal 732.

The outputs of differential amplifier 703 and differential amplifier 734 are subtracted from each other to produce an output 733 of envelope detector 700. In one exemplary embodiment, the drain, collector or other conducting terminal of transistor 722 is connected to the drain, collector or other conducting terminal of transistor 728, and the drain, collector or other conducting terminal of transistor 723 is connected to the drain, collector or other conducting terminal of transistor 727 to produce a differential current at output 733. Other suitable configurations can also or alternatively be used to perform this subtraction.

Output 733 has reduced sensitivity to even-order harmonics present in the RF input signal, such as by canceling or partially canceling the contribution of the harmonic present on output signals 712 and 731 through subtraction at output 733. Output 733 also has reduced offset voltage by canceling an offset voltage present of output signal 712 with offset signal 713 and by canceling an offset voltage of output signal 731 with offset signal 732.

In operation, envelope detector 700 detects the envelope of an input RF signal without degradation from even-order harmonics, such as second harmonics, that may be present in the signal. In this manner, envelope detector 700 may not require even-harmonic second harmonic filters to be used, which can create noise or other undesired effects on other system components and which increase the cost and size of the overall circuit.

In view of the above detailed description of the present invention and associated drawings, other modifications and variations are apparent to those skilled in the art. It is also apparent that such other modifications and variations may be effected without departing from the spirit and scope of the present invention.

What is claimed is:

1. A system for detecting the envelope of a signal comprising:
a first envelope detector generating a first envelope signal of an input RF signal;
a second envelope detector generating a second envelope signal of the input RF signal; and
a signal combiner receiving the first envelope signal and the second envelope signal and generating an even-order harmonic compensated envelope signal.

2. The system of claim 1 wherein the first envelope signal represents a positive peak envelope value of the input RF signal.

3. The system of claim 1 wherein the second envelope signal represents a negative peak envelope value of the input RF signal.

4. The system of claim 1 wherein the first envelope detector comprises a PNP transistor, a p-type FET, or other suitable devices for detecting negative peak voltages.

5. The system of claim 1 wherein the first envelope detector comprises an NPN transistor, an n-type FET, or other suitable devices for detecting positive peak voltages.

6. The system of claim 1 wherein the first envelope detector comprises a PNP transistor, a p-type FET, or other suitable devices for detecting negative peak voltages, and the second envelope detector comprises an NPN transistor, an n-type FET, or other suitable devices for detecting positive peak voltages.

7. The system of claim 1 wherein the first envelope detector comprises a replica circuit reducing an offset of the first envelope signal.

8. A method for detecting the envelope of a signal comprising:
generating a first envelope signal of an input RF signal;
generating a second envelope signal of the input RF signal;
combining the first envelope signal and the second envelope signal; and
generating an even-order harmonic compensated envelope signal from the combined first envelope signal and second envelope signal.

9. The method of claim 8 wherein generating the first envelope signal comprises generating a positive peak envelope value of the input RF signal.

10. The method of claim 8 wherein generating the second envelope signal comprises generating a negative peak envelope value of the input RF signal.

11. The method of claim 8 wherein generating the first envelope signal comprises generating a positive peak envelope value of the input RF signal, and generating the second envelope signal comprises generating a negative peak envelope value of the input RF signal.

12. The method of claim 8 wherein generating the first envelope signal further comprises generating a replica envelope signal to reduce an offset of the first envelope signal.

13. A system for detecting the envelope of a signal comprising:
means for generating a first envelope signal of an input RF signal;
means for generating a second envelope signal of the input RF signal; and
means for receiving the first envelope signal and the second envelope signal and generating an even-order harmonic compensated envelope signal.

14. The system of claim 13 wherein the first envelope signal represents a positive peak envelope value of the input RF signal.

15. The system of claim 13 wherein the second envelope signal represents a negative peak envelope value of the input RF signal.

16. The system of claim 1 wherein the means for generating the first envelope signal comprises means for reducing an offset of the first envelope signal.

17. The system of claim 1 wherein the means for generating the first envelope signal comprises means for reducing an offset of the first envelope signal and the means for generating the second envelope signal comprises means for reducing an offset of the second envelope signal.
